(19) United States
(12) Patent Application Publication
(10) Pub. No.: US 2024/0230769 A1
(43) Pub. Date: Jul. 11, 2024

(54) ESTIMATION DEVICE, ENERGY STORAGE APPARATUS, AND ESTIMATION METHOD

(71) Applicant: GS Yuasa International Ltd., Kyoto-shi, Kyoto (JP)

(72) Inventor: Yuki IMANAKA, Kyoto (JP)

(21) Appl. No.: 18/563,632

(22) PCT Filed: May 18, 2022
(86) PCT No.: PCT/JP2022/020636

§ 371 Date: Nov. 22, 2023

(30) Foreign Application Priority Data
May 28, 2021 (JP) 2021-090029

(51) Int. Cl. G01R 31/374; B60L 58/12; G01R 31/396

(52) U.S. Cl. CPC G01R 31/374; B60L 58/12; G01R 31/396; B60L 2240/547

(57) ABSTRACT

An estimation device for estimating a residual electricity amount of an energy storage cell or an assembled battery is configured to perform: first processing of estimating the residual electricity amount based on an integrated value of a current of the energy storage cell or the assembled battery; second processing of estimating an accumulated error of the residual electricity amount based on an integrated value of a measurement error of the current; third processing of estimating the residual electricity amount by a method that differs from the first processing; fourth processing of calculating a residual electricity amount difference that is a difference between the residual electricity amount estimated in the first processing and the residual electricity amount estimated in the third processing; and fifth processing of calculating a correction value of the measurement error based on the accumulated error and the residual electricity difference.

### CROSS REFERENCE TO RELATED APPLICATIONS

This application is a National Stage Application, filed under 35 U.S.C. § 371, of International Application No. PCT/JP2022/020636, filed May 18, 2022, which international application claims priority to and the benefit of Japanese Application No. 2021-090029, filed May 28, 2021; the contents of both of which as are hereby incorporated by reference in their entireties.

### BACKGROUND

### Technical Field

The present invention relates to a technique for enhancing estimation accuracy of a residual electricity amount of an energy storage cell or of an assembled battery by correcting a measurement error of a current.

### Description of Related Art

There has been known a technique where a current or a voltage of an energy storage cell or an assembled battery is measured, and a residual electricity amount of the energy storage cell or the assembled battery is estimated based on the result of the measurement (for example, Patent Document JP-A-2010-283922 described below).

### BRIEF SUMMARY

As one of methods for estimating a residual electricity amount of an energy storage cell or an assembled battery, there has been known a current integration method. In the current integration method, an error, which is caused by a measurement error included in a current measurement value, is accumulated on an estimation result (hereinafter, such an error accumulated on the estimation result of the residual electricity amount is referred to as an “accumulated error”.).

The present invention discloses a technique for obtaining a correction value of a current measurement error and improving estimation accuracy of an accumulated error.

An estimation device for estimating a residual electricity amount of an energy storage cell or an assembled battery performs: first processing of estimating the residual electricity amount based on an integrated value of a current of the energy storage cell or the assembled battery; second processing of estimating an accumulated error of the residual electricity amount based on an integrated value of a measurement error of the current; third processing of estimating the residual electricity amount by a method that differs from the first processing; fourth processing of calculating a residual electricity amount difference that is a difference between the residual electricity amount estimated in the first processing and the residual electricity amount estimated in the third processing; and fifth processing of calculating a correction value of the measurement error based on the accumulated error and the residual electricity amount difference.

Examples of the “residual electricity amount” include a residual capacity [Ah], a state of charge (SOC) [%], and the like of the energy storage cell or the assembled battery.

The present invention is applicable to an energy storage apparatus, and is also applicable to a residual electricity amount estimation method and a residual electricity amount estimation program of the energy storage apparatus.

According to this configuration, it is possible to acquire a correction value of a measurement error of a current that flows through the energy storage cell or the assembled battery. Estimation accuracy of an accumulated error can be enhanced by correcting a measurement error based on a correction value.

### BRIEF DESCRIPTION OF THE FIGURES

FIG. 1 is a side view of an automobile.

FIG. 2 is an exploded perspective view of a battery.

FIG. 3 is a plan view of a secondary battery cell.

FIG. 4 is a cross-sectional view of the secondary battery cell taken along a line A-A in FIG. 3.

FIG. 5 is a block diagram illustrating an electrical configuration of an automobile.

FIG. 6 is a block diagram showing an electrical configuration of the battery.

FIG. 7 illustrates a waveform of a current near full charging of electricity.

FIG. 8 is a diagram illustrating a relationship between the transition of an SOC and a current integration time.

FIG. 9 is a flowchart of SOC estimation processing.

FIG. 10 is a diagram illustrating an SOC estimation range.

FIG. 11 is a diagram illustrating an SOC-OCV correlation characteristic of secondary battery cells.

### DETAILED DESCRIPTION OF VARIOUS EMBODIMENTS

### Overall Configuration of Estimation Device

(1) An estimation device for estimating a residual electricity amount of an energy storage cell or an assembled battery performs: first processing of estimating the residual electricity amount based on an integrated value of a current of the energy storage cell or the assembled battery; second processing of estimating an accumulated error of the residual electricity amount based on an integrated value of a measurement error of the current; third processing of estimating the residual electricity amount by a method that differs from the first processing; fourth processing of calculating a residual electricity amount difference that is a difference between the residual electricity amount estimated in the first processing and the residual electricity amount estimated in the third processing; and fifth processing of calculating a correction value of the measurement error based on the accumulated error and the residual electricity amount difference.

In such a configuration, a residual electricity amount is estimated based on an integrated value of a current of the energy storage cell or the assembled battery (first processing), and an accumulated error of the residual electricity amount is estimated based on an integrated value of a measurement error of the current (second processing). The measurement error is an arbitrary value set based on a statistical value or an experimental value in place of a true value of an error that is difficult to directly measure.

The residual electricity amount of the energy storage cell or the assembled battery is estimated by a method that differs from the first processing (third processing). A residual electricity amount difference that is a difference between the residual electricity amount estimated in the first processing and the residual electricity amount estimated in the third processing is calculated (fourth processing). The residual electricity amount estimated in the third processing is not based on the integrated value of the current and hence, an error caused by the current is not included. Accordingly, the residual electricity amount difference calculated in the fourth processing reflects a value obtained by accumulating errors attributed to the current.

As an error attributed to a current, a gain error and an offset error are named. The gain error is canceled by repeating charging of electricity and discharging of electricity. Accordingly, to improve the estimation accuracy of the residual electricity amount, it is required to reduce the influence of an offset error. An accumulated value of the offset error is included in the residual electricity amount difference calculated in the fourth processing.

A correction value of the measurement error is calculated based on the accumulated error and the residual electricity amount difference obtained as described above (fifth processing). By obtaining the correction value of the measurement error, it is possible to determine whether or not the value of the measurement error used in the second processing is valid. For example, when the calculated correction value is a negligibly small value, it can be determined that the value of the measurement error used in the second processing is appropriate, and the accuracy of the accumulated error estimated based on the measurement error is sufficiently high. In a case where the calculated correction value is an extremely large value, it can be determined that the value of the measurement error used in the second processing is unreasonable. Accordingly, it is determined that the correction is required or that there is a possibility that an abnormality has occurred in the current measurement circuit or the like.

(2) The measurement error may be corrected based on the correction value calculated in the fifth processing (sixth processing), and the second processing may be performed using the corrected measurement error after performing the sixth processing. With such a configuration, the value of the measurement error can be brought close to the true value by the correction and hence, the estimation accuracy of the accumulated error can be improved. When the estimation accuracy of the accumulated error is improved, the estimation accuracy of the residual electricity amount of the energy storage cell or the assembled battery based on the integrated value of the current is improved. Accordingly, it possible to estimate the residual electricity amount of the energy storage cell or the assembled battery with high accuracy and hence, the battery performance of the energy storage cell or the assembled battery can be maximized.

(3) In a case where a difference between the accumulated error and the residual electricity amount difference exceeds a threshold, the estimation device may perform the sixth processing so as to correct the measurement error. In a case where the difference between the accumulated error and the residual electricity amount difference is large, it is predicted that the accumulated error which is the accumulated value of the measurement errors is large. Specifically, this is a case where the accumulated error is large as a result of setting the measurement error to a value larger than the true value. By performing the sixth processing thus correcting the measurement error, the measurement error can be brought close to the true value. Accordingly, it is possible to enhance the accuracy of the estimation of the residual electricity amount of the energy storage cell or the assembled battery based on an integrated value of a current and hence, the battery performance of the energy storage cell or the assembled battery can be maximized.

(4) In the third processing, the residual electricity amount of the energy storage cell or the assembled battery may be estimated by a full charging detection method where the energy storage cell or the assembled battery is charged to a fully charged state.

The measurement error of the current is not accumulated in the residual electricity amount estimated by the full charging detection method. Accordingly, the estimation accuracy is higher than the corresponding estimation accuracy of the residual electricity amount estimated based on the integrated value of the current. In the fourth processing, the residual electricity amount estimated in the first processing can be corrected with high accuracy based on the residual electricity amount estimated by the full charging detection method. As a result, a highly accurate correction value can be obtained in the fifth processing.

(5) The energy storage apparatus includes: the energy storage cell or the assembled battery; the current measurement unit that measures a current of the energy storage cell or the assembled battery, and the above estimation device. Accordingly, the accuracy of the estimation of the residual electricity amount of the energy storage cell or the assembled battery can be enhanced by the estimation device and hence, the performance of the energy storage cell or the assembled battery can be maximized.

### Embodiment 1

### 1. Description of Battery

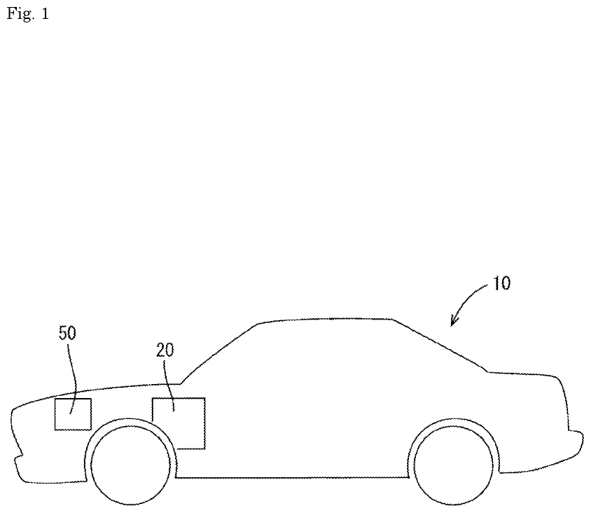

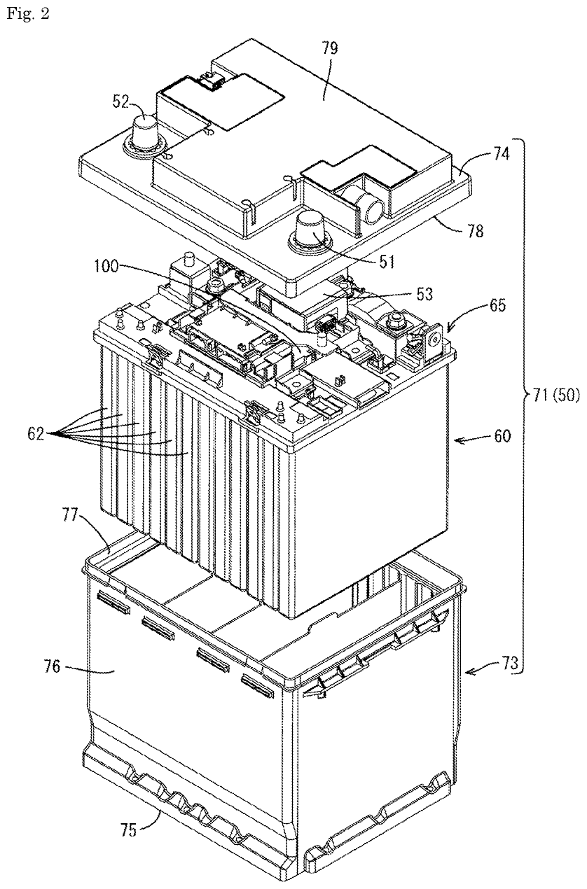

FIG. 1 is a side view of an automobile 10, and FIG. 2 is an exploded perspective view of a battery 50. The automobile 10 is an engine driven vehicle, and includes the battery 50. On the automobile 10, in place of the engine (an internal combustion engine), an energy storage apparatus or a fuel battery for driving the vehicle may be mounted. In FIG. 1, only the automobile 10, the engine 20 and the battery 50 are illustrated, and other parts that construct the automobile 10 are omitted. The automobile 10 is an example of a “vehicle”, and the battery 50 is an example of an “energy storage apparatus”.

As illustrated in FIG. 2, the battery 50 includes an assembled battery 60, a circuit board unit 65, and a container 71.

The container 71 includes a body 73 made of a synthetic resin material, and a lid body 74. The body 73 has a bottomed cylindrical shape. The body 73 includes a bottom surface portion 75 and four side surface portions 76. An upper opening portion 77 is formed at an upper end portion of the body 73 by four side surface portions 76.

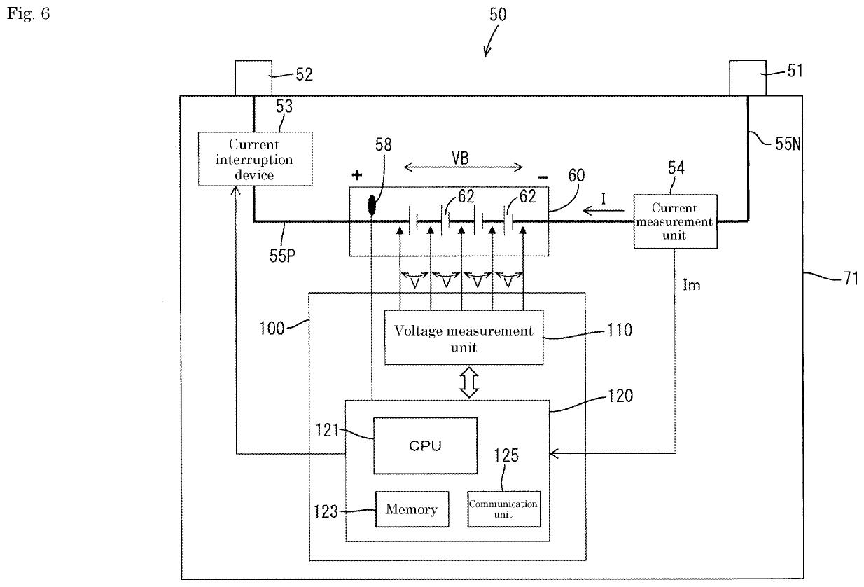

The container 71 contains the assembled battery 60 and the circuit board unit 65. In the configuration illustrated in FIG. 2, the assembled battery 60 has twelve secondary battery cells 62. The secondary battery cell 62 is an example of “an energy storage cell”. Twelve secondary battery cells 62 are connected with each other in three parallels and four series. The circuit board unit 65 is disposed above the assembled battery 60. In the block diagram in FIG. 6, three secondary battery cells 62 that are connected in parallel are indicated by one battery signal.

The lid body 74 illustrated in FIG. 2 closes the upper opening portion 77 of the body 73. An outer peripheral wall 78 is formed on a periphery of the lid body 74. The lid body 74 has a protruding portion 79 having an approximately T shape as viewed in a plan view. On a front portion (on a left front side in FIG. 2) of the lid body 74, a positive external terminal 52 is fixed to one corner portion, and a negative external terminal 51 is fixed to the other corner portion.

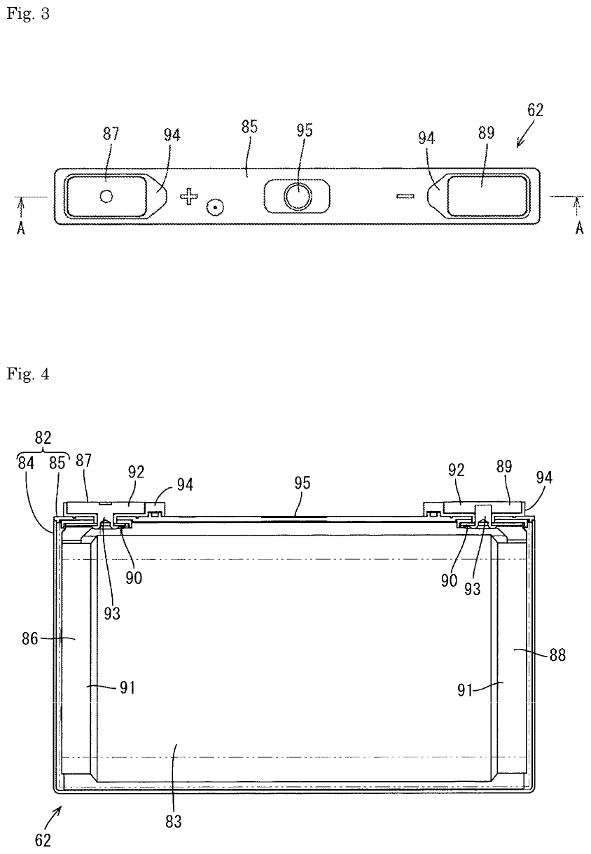

As illustrated in FIG. 3 and FIG. 4, the secondary battery cell 62 is configured such that an electrode assembly 83 is accommodated in a case 82 having a rectangular parallelepiped shape together with a nonaqueous electrolyte. In the embodiment, the secondary battery cell 62 is formed of a lithium ion secondary battery. The case 82 includes a case body 84 and a lid 85 that closes an opening portion formed at an upper portion of the case body 84.

The secondary battery cell 62 is not limited to a prismatic cell illustrated in FIG. 3 and FIG. 4, and may be a cylindrical cell or a pouch cell having a laminate film case.

The electrode assembly 83 is formed such that a separator formed of a porous resin film is disposed between a negative electrode element that is formed by applying an active material to a substrate formed of a copper foil, and a positive electrode element that is formed by applying an active material to a substrate formed of an aluminum foil. These elements all have a strip shape, and are wound in a flat shape so as to be accommodated in the case body 84 in a state where the position of the negative electrode element and the position of the positive electrode element are displaced toward opposite sides in the width direction with respect to the separator.

The electrode assembly 83 may be of a stacked type instead of a wound type.

A positive terminal 87 is connected to the positive electrode element via a positive electrode current collector 86, and a negative terminal 89 is connected to the negative electrode element via a negative electrode current collector 88 (see FIG. 4). The positive electrode current collector 86 and the negative electrode current collector 88 are each formed of a flat plate-like pedestal portion 90 and a leg portion 91 extending from the pedestal portion 90. A through hole is formed in the pedestal portion 90. The leg portion 91 is connected to the positive electrode element or the negative electrode element.

The positive terminal 87 and the negative terminal 89 each include: a terminal body portion 92; and a shaft portion 93 protruding downward from a center portion of a lower surface of the terminal body portion 92. In such a configuration, the terminal body portion 92 and the shaft portion 93 of the positive terminal 87 are integrally formed with each other using aluminum (a single material). In the negative terminal 89, the terminal body portion 92 is made of aluminum, and the shaft portion 93 is made of copper. The negative terminal 89 is formed by assembling the terminal body portion 92 and the shaft portion 93 to each other. The terminal body portion 92 of the positive terminal 87 and the terminal body portion 92 of the negative terminal 89 are disposed at both end portions of the lid 85 via gaskets 94 made of an insulating material. The terminal body portion 92 of the positive terminal 87 and the terminal body portion 92 of the negative terminal 89 are exposed outward from the gaskets 94.

The lid 85 has a pressure release valve 95. As illustrated in FIG. 3, the pressure release valve 95 is positioned between the positive terminal 87 and the negative terminal 89. The pressure release valve 95 is released when an internal pressure in the case 82 exceeds a limit value so as to lower the internal pressure in the case 82.

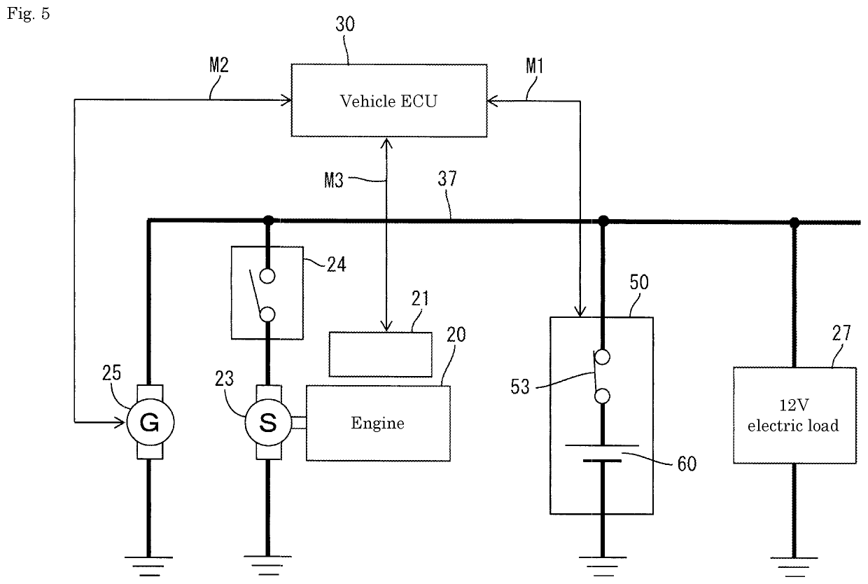

FIG. 5 is a block diagram illustrating an electrical configuration of the automobile 10, and FIG. 6 is a block diagram illustrating an electrical configuration of the battery 50.

As illustrated in FIG. 5, the automobile 10 includes: the engine 20 that is a driving device; an engine control unit 21; an engine starting device 23; an alternator 25 that is a generator of the vehicle; an electric load 27; a vehicle electronic control unit (ECU) 30; and the battery 50.

The battery 50 is connected to an electricity supply line 37. The engine starting device 23, the alternator 25, and the electric load 27 are connected to the battery 50 via the electricity supply line 37.

The engine starting device 23 includes a starter motor. When an ignition switch 24 is turned on, a cranking current flows from the battery 50, and the engine starting device 23 is driven. A crankshaft is rotated by driving the engine starting device 23 so that the engine 20 can be started.

The electric load 27 is an electric load mounted on the automobile 10 other than the engine starting device 23. The electric load 27 has a rated voltage of 12V. The electric load 27 is an auxiliary device such as an air conditioner, an audio system, or a car navigation system.

The alternator 25 is a vehicle generator that generates electricity by the power of the engine 20. In a case where an electricity generation amount of the alternator 25 exceeds an electricity consumption amount consumed by the vehicle load of the automobile 10, the battery 50 is charged with electricity generated by the alternator 25. In a case where a power generation amount of the alternator 25 is smaller than a power consumption amount consumed by the vehicle load of the automobile 10, the battery 50 is discharged so as to compensate for a shortage of the power generation amount.

The vehicle ECU 30 is communicably connected to the battery 50 via a communication line M1, and is communicably connected to the alternator 25 via the communication line M2. The vehicle ECU 30 receives information relating to a state of charge (SOC) from the battery 50, and controls the SOC of the battery 50 by controlling an electricity generation amount of the alternator 25.

The vehicle ECU 30 is communicably connected to the engine control unit 21 via a communication line M3. The engine control unit 21 is mounted on the automobile 10, and monitors an operation state of the engine 20.

The engine control unit 21 monitors a traveling state of the automobile 10 based on measured values of meters such as a speed measuring instrument. The vehicle ECU 30 can obtain information relating to whether the ignition switch 24 is turned on or off, information relating to an operation state of the engine 20, and information relating to a traveling state (traveling, traveling stopped, idling stop or the like) of the automobile 10 from the engine control unit 21.

As illustrated in FIG. 6, the battery 50 includes a current interruption device 53, the assembled battery 60, a current measurement unit 54, a temperature sensor 58, and a management device 100. The battery 50 is a battery having a rated voltage of 12V.

The current interruption device 53, the assembled battery 60, and the current measurement unit 54 are connected in series via a power line 55P, and 55N. The power line 55P connects the positive external terminal 52 and the positive electrode of the assembled battery 60 to each other. The power line 55N connects the negative external terminal 51 and the negative electrode of the assembled battery 60 to each other.

The current interruption device 53 is provided to the positive power line 55P. The current measurement unit 54 is provided to the negative power line 55N.

As the current interruption device 53, a contact switch (a mechanical type switch) such as a relay or a semiconductor switch such as an FET can be used. The current interruption device 53 is constantly controlled to be in a closed state. When an abnormality occurs in the battery 50, a current is interrupted by opening the current interruption device 53 and hence, it is possible to protect the battery 50.

The current measurement unit 54 measures a current I [A] of the assembled battery 60, and outputs a current measurement value Im to a control unit 120. A current detection resistor or a magnetic sensor can be used as the current measurement unit 54.

The temperature sensor 58 is mounted on a side surface of the assembled battery 60, measures a temperature of the assembled battery 60, and outputs the measured temperature to the control unit 120.

The management device 100 is mounted on the circuit board unit 65 (see FIG. 2). The management device 100 includes a voltage measurement unit 110 and the control unit 120. The control unit 120 is an example of an “estimation device”.

The voltage measurement unit 110 is connected to both ends of each secondary battery cell 62 by a signal lines, and measures a cell voltage V of each secondary battery cell 62. The voltage measurement unit 110 outputs the cell voltages V of respective secondary battery cells 62 and an inter-terminal voltage VB of the assembled battery 60 obtained by summing all these voltages V to the control unit 120.

The control unit 120 includes: a CPU 121 having an arithmetic operation function; a memory 123 that is a storage unit, and a communication unit 125. The communication unit 125 is provided for communication with the vehicle ECU 30.

The control unit 120 monitors the state of the battery 50 by monitoring information relating to a measured current Im, a total voltage VB, and a temperature of the assembled battery 60. The control unit 120 also monitors the cell voltages V of the respective secondary battery cells 62.

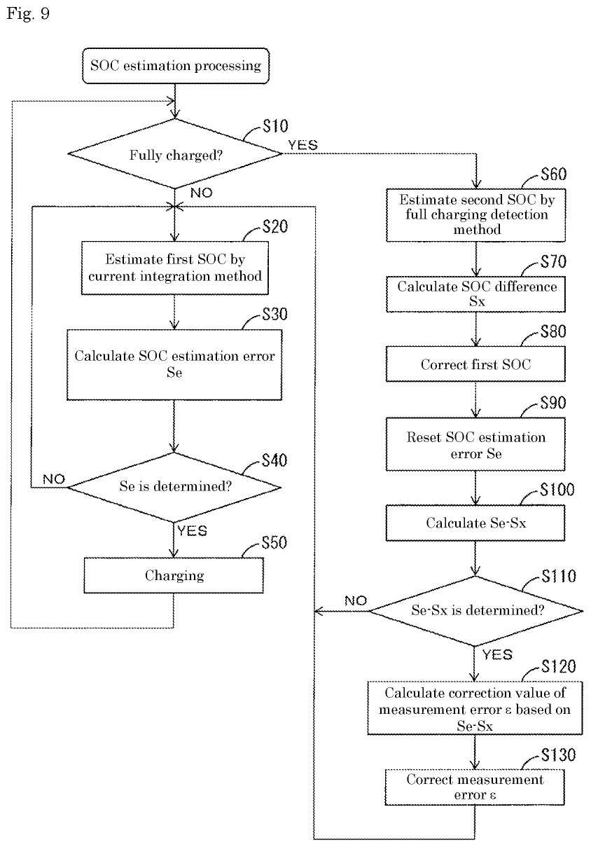

The memory 123 is a nonvolatile storage medium such as a flash memory or an EEPROM. The memory 123 stores a program for monitoring the state of the assembled battery 60, an estimation program of a SOC (a program of performing the flow illustrated in FIG. 9), and data necessary for executing respective programs.

### 2. Method of Estimating Residual Electricity Amount of Assembled Battery

In the present invention, the secondary battery cell 62 is an LFP/Gr-based (iron phosphate-based) lithium ion secondary battery cell that uses lithium iron phosphate (LiFePO₄) as a positive active material and graphite as a negative active material. In FIG. 2, one assembled battery 60 is formed by connecting 12 secondary battery cells 62 in 3 parallel and 4 series. However, one assembled battery 60 is formed by connecting four secondary battery cells 62 in series.

A current I having the same magnitude flows through the respective secondary battery cells 62 that form the assembled battery 60. A voltage VB of the assembled battery 60 is a value obtained by summing the voltages V of four respective secondary battery cells 62 that are connected in series. In the estimation of a residual electricity amount described below, a residual electricity amount of the assembled battery 60 is estimated.

The description is made using an SOC as a physical quantity that expresses a residual electricity amount of the assembled battery 60. The SOC is a ratio [%] of a residual capacity Cr [Ah] to a full-charge capacity Co [Ah] of the assembled battery 60, and is expressed by the following formula (1). The full-charge capacity Co is an electricity amount that can be discharged from the fully charged assembled battery 60.

$$SOC = ( Cr / Co ) \times 100 \qquad ( 1 )$$

As a method of estimating the SOC based on an integrated value of a current, there has been known a current integration method. The current integration method estimates the SOC[%] based on a time integrated value of a current I as expressed in the formula (2). Assume that the symbol of the current I takes “plus” at the time of charging electricity and takes “minus” at the time of discharging electricity.

$$SOC = SOCo + 100 \times ( \int Idt ) / Co \qquad ( 2 )$$

SOCo is an initial value of the SOC, I is a current, and t is an integrated time.

As expressed in the following formula (3), a current measurement value Im acquired by the current measurement unit 54 includes a measurement error ε.

$$Im = Ic + ε \qquad ( 3 )$$

Im is a current measurement value, Ic is a true value of the current, and ε is a measurement error.

In the following description, the SOC estimated by the current integration method is referred to as a first SOC. In the estimation of the first SOC, along with the accumulation of a measurement error ε accompanying the supply of electricity, an error of the SOC (an SOC estimation error Se described later) is increased. As errors that are included in the measurement error ε, a gain error and an offset error (errors that are detected even in a non-current state) are known. Since the gain error is canceled by charging and discharging, it is considered that the offset error is dominant as the measurement error ε.

The SOC estimation error Se can be expressed by the following formula (4) using the measurement error ε. The SOC estimation error Se is an example of an “accumulated error”.

$$Se = ( \int ε dt ) / Co \times 100 \qquad ( 4 )$$

In the current integration method, a measurement error ε is accumulated and hence, there is a concern that the SOC estimation error Se is increased with the lapse of time. By correcting the first SOC estimated by the current integration method based on the SOC estimated by a method different from the current integration method, the SOC estimation error Se can be suppressed, and the estimation accuracy of the first SOC can be improved.

As one of methods of estimating an SOC based on a voltage of the energy storage cell, a full charging detection method is known. The full charging detection method is a method where, in a case where the control unit 120 detects that the assembled battery 60 is charged to a voltage corresponding to full charging, the SOC at this point of time is estimated as 100% or a predetermined set value close to 100%. In the following description, the SOC estimated by the full charging detection method is referred to as a second SOC, and the second SOC at a point of time that the assembled battery 60 is charged to a voltage corresponding to full charging is assumed as 100%.

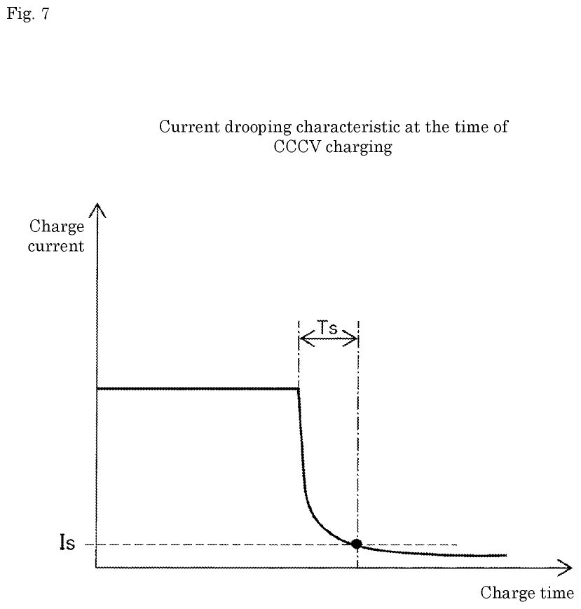

Determination whether or not the assembled battery 60 is charged to a voltage that corresponds to full charging can be determined based on whether or not a predetermined full charging completion condition is satisfied. For example, in a case of constant voltage charging, the determination whether or not the assembled battery 60 is charged to a voltage that corresponds to full charging can be determined based on a charging time Ts after a voltage VB of the assembled battery 60 reaches a predetermined target voltage or by comparing a drooping current value with a threshold current Is (see FIG. 7). The determination whether or not the assembled battery 60 is fully charged may be made based on whether a total voltage VB of the assembled battery 60 is equal to or more than a predetermined value or whether a current measurement value Im is equal to or less than a predetermined value.

In this embodiment, a first SOC estimated by the current integration method is corrected based on a second SOC estimated by a full charging detection method, and thereafter, the first SOC is estimated by the current integration method using the corrected first SOC as an initial value.

For example, in a case where a full-charging capacity is 60 [Ah] and a residual capacity that is estimated by a current integration method immediately before the detection of full-charging is 59.528 [Ah], the residual capacity is corrected from 59.528 [Ah] to 60 [Ah] after the detection of full-charging. After the correction of the residual capacity, the first SOC is estimated by the current integration method using the residual capacity 60 [Ah] as an initial value. That is, the first SOC is estimated with the initial value set to 100 [%].

The SOC difference Sx expressed by the following formula (5) is an SOC difference obtained by subtracting the first SOC estimated by the current integration method from the second SOC estimated by the full charging detection method. Sx indicates a true value of the SOC estimation error Se by a current integration method or a value close to such a true value. The SOC difference Sx is an example of a “residual electricity amount difference”.

$$Sx = ( second SOC - first SOC ) \qquad ( 5 )$$

For example, in a case where a residual capacity estimated by a current integration method immediately before the full charging is detected is 59.528 [Ah], such a value is converted into 99.21 [%] in terms of the first SOC. Accordingly, the SOC difference Sx is 0.79 [%] (100 [%]−99.21 [%]=0.79 [%]).

A correction value As of a measurement error & included in a current measurement value Im is calculated based on the SOC estimation error Se calculated by the formula (4) and the SOC difference Sx calculated by the formula (5) (the following formula (6)).

$$Δε = k \times ( Se - Sx ) / T \qquad ( 6 )$$

T is a current integration time, and k is a predetermined coefficient.

The current integration time T is a time for integrating the current measurement value Im in estimating the first SOC by the current integration method. Specifically, the current integration time T is a time from a point of time that the estimation of the first SOC is started to a point of time immediately before the full charging is detected.

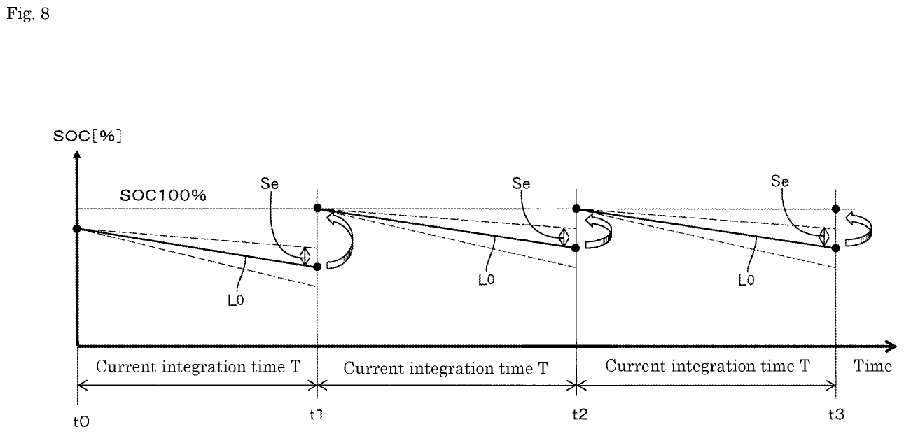

FIG. 8 is an example of a graph plotting a change in an estimated value L0 of the first SOC with the lapse of time. In FIG. 8, the first SOC is corrected to 100% at points of time t1, t2, and t3. In the case of the first cycle, a period from a point of time t0 to a point of time t1 is the current integration time T. In the case of the second cycle, a period from the point of time t1 to the point of time t2 is the current integration time T. In the case of the third cycle, a period from the point of time t2 to the point of time t3 is the current integration time T. Dotted lines that sandwich the estimated value L0 of the first SOC indicates a range of the SOC estimation error Se about the estimated value L0.

As expressed by the following formula (7), the measurement error ε of the current measurement value Im can be corrected using the correction value Δε obtained by the equation (6).

$$ε1 = ε - Δε \qquad ( 7 )$$

ε1 is a measurement error after correction, and ε is a measurement error before correction.

The correction of the measurement error ε improves the estimation accuracy of the SOC estimation error Se. By improving the estimation accuracy of the SOC estimation error Se, the SOC estimation range can be narrowed as compared with a case where the measurement error ε is estimated to a value larger than the true value.

### 3. Control Flow of SOC Estimation Processing

FIG. 9 is a flowchart of SOC estimation processing. The SOC estimation processing includes steps S10 to S130, and is performed at a predetermined arithmetic operation cycle after starting an operation of the control unit 120. It is assumed that an initial value SOCo of the first SOC and an initial value of the measurement error & are stored in the memory 123 in advance. As the initial value of the measurement error ε, a statistical value or an experimental value is used. In the following example, assume that the initial value of the measurement error ε is 4.8 [mA].

When the control unit 120 starts the SOC estimation processing, the control unit 120 determines whether or not the assembled battery 60 is in a fully charged state based on a voltage VB of the assembled battery 60 (S10). When the SOC does not satisfy the above-described full-charge completion condition, it is determined that the assembled battery 60 is not fully charged.

When the assembled battery 60 is not fully charged with electricity (S10: NO), the control unit 120 estimates the first SOC of the assembled battery 60 by the current integration method (S20). Specifically, the control unit 120 integrates the current measurement values Im measured by the current measurement unit 54 as expressed in the formula (2), adds or subtracts the current measurement value Im to or from the initial value SOCo of the SOC so as to estimate the first SOC, and stores the result in the memory 123.

For example, in a case where the full-charging capacity=60 [Ah], the current measurement value Im=1 [A], an arithmetic operation cycle 0.1 [s], the previous-time value of the residual capacity=59.5 [Ah], and the first SOC=99.17 [%], a charging electricity amount after the lapse of 1000 cycles becomes 0.028 [Ah]. 1 [A]×0.1 [s]×1000/3600≈0.028 [Ah]. Accordingly, an updated value of the residual capacity is 59.528 [Ah] (=59.5+0.028), and the updated value of the first SOC is 99.21 [%]. Step S20 is an example of “first processing” and “first step”.

Next, the control unit 120 calculates the SOC estimation error Se using the measurement error ε stored in the memory 123 (S30). The control unit 120 calculates an SOC estimation error Se based on the formula (4), and stores the result in the memory 123.

For example, when the measurement error ε=4.8 [mA] and the value obtained by converting the previous value of the SOC estimation error Se into the capacity is 800 [mAh], the error accumulation amount Cx accumulated when 1000 cycles have elapsed is 800 [mAh]+4.8 [mA]×0.1×1000 [s]/3600≈800.13 [mAh]. At this point of time, an updated value of the SOC estimation error Se becomes 1.33 [%] (ε800.13 [mAh]/60 [Ah]×100). Step S30 is an example of “second processing” and “second step”.

Next, the control unit 120 determines an SOC estimation error Se (S40). Specifically, an absolute value of the SOC estimation error Se is compared with a threshold TH1. The threshold TH1 is an arbitrary value set corresponding to the estimation accuracy required by the first SOC. When an SOC estimation error Se is smaller than the threshold TH1 (S40: NO), the control unit 120 determines that it is unnecessary to correct the first SOC. In this case, the processing advances to step S20, and the estimation of the first SOC by a current integration method is continued.

With respect to the SOC estimation error Se, the longer the integrated time t becomes, the larger the measurement error ε becomes due to accumulation, and soon the measurement error ε becomes equal to or larger than the threshold TH1.

In a case where an absolute value of the SOC estimation error Se becomes equal to or larger than the threshold TH1, the control unit 120 determines that the SOC estimation accuracy Se is large and it is necessary to correct the measurement error ε (S40: YES), and instructs the vehicle ECU 30 to charge electricity to the assembled battery 60 (S50).

Even during the charging of electricity to the assembled battery 60, the control unit 120 continues the estimation of the first SOC by the current integration method until the assembled battery 60 satisfies a full charging completion condition, and stores the result of the estimation in the memory 123 one by one. In a case where a full charging completion condition is satisfied, the control unit 120 determines that the assembled battery 60 is fully charged with electricity. (S10: YES).

Thereafter, the control unit 120 estimates the second SOC by the full charging detection method (S60). Specifically, the control unit 120 estimates that the second SOC is 100%. Step S60 is a process of estimating the SOC by a method different from the current integration method (full charging detection method), and is an example of “third process” and “third step”.

Next, the control unit 120 calculates the SOC difference Sx based on formula (5) (S70).

In a case where the first SOC immediately before the full charging detection is 99.21 [%], the SOC difference Sx is 0.79 [%]. In a case where an estimated value of a residual capacity obtained by a current integration method immediately before the full charging detection is 59.528 [Ah], a capacity corresponding to a SOC difference Sx is 0.472 [Ah]. Step S70 is an example of “fourth processing” and “fourth step”.

Next, the control unit 120 corrects the first SOC estimated by a current integration method based on a second SOC estimated by a full charging detection method (S80).

For example, in a case where a full-charging capacity is 60 [Ah] and a residual capacity estimation value immediately before the detection of full-charging by the current integration method is 59.528 [Ah], a residual capacity estimated value is corrected to 60 [Ah] so that the first SOC is corrected to 100[%].

After the correction, the control unit 120 resets the SOC estimation error Se to zero (S90). In the above example, the SOC estimation error Se is reset to 1.33 (Se=1.33 [%]). By resetting the SOC estimation error Se, an error accumulation amount Cx is also reset to 800.13 [mAh](Cx=800.13 [mAh]).

Next, the control unit 120 subtracts the SOC difference Sx calculated in step S70 from the SOC estimation error Se immediately before the detection of the full-charging calculated in step S30 (S100).

In the above example, the SOC difference Sx is 0.79 [%] and the SOC estimation error Se is 1.33 [%] and hence, (Se−Sx) is 0.54 [%]. In terms of capacity, the above is expressed as a relationship that 800.13 [mAh]−0.472 [Ah]≈328 [mAh]. Step S100 is an example of “fifth processing” and “fifth step”.

Thereafter, the control unit 120 determines the magnitude of the absolute value of (Se−Sx). Specifically, the absolute value of (Se−Sx) is compared with a threshold TH2 (S110). The threshold TH2 is an arbitrary value set corresponding to the accuracy required by the measurement error ε.

In a case where an absolute value of (Se−Sx) is smaller than a threshold TH2 (S110: NO), the control unit 120 determines that it is not necessary to correct the measurement error ε.

In this case, the processing advances to S20 without correcting the measurement error ε. The control unit 120 estimates the first SOC by a current integration method using the measurement error ε stored in the memory 123 as it is. That is, the control unit 120 estimates the first SOC based on the formula (2) using the first SOC corrected in step S80 as an initial value.

In a case where an absolute value of (Se−Sx) is equal to or more than a threshold TH2 (S110: YES), the control unit 120 determines that it is necessary to correct the measurement error ε. In this case, the control unit 120 calculates a correction value Δε of the measurement error ε by the formula (6) based on the value of (Se−Sx) calculated in step S100 (S120).

Next, the control unit 120 corrects the measurement error ε by formula (7) using the correction value As calculated in step S120 (S130), and stores a corrected measurement error ε1 in the memory 123. Step S130 is an example of the “sixth processing”.

Thereafter, the processing advances to S20, and the control unit 120 estimates the first SOC by the current integration method using the corrected measurement error ε1. By performing such processing, the estimation accuracy of the SOC estimation error Se can be improved.

### Example of Determination in S110

In S110, an absolute value of (Se−Sx) is compared with the threshold TH2. In a case where the absolute value of (Se−Sx) is equal to or larger than the threshold TH2, the control unit 120 determines that it is necessary to correct the measurement error ε. The threshold TH2 may be a fixed value or may be changed corresponding to the current integration time T.

The measurement error ε can be expressed by the following formula (8) as a sum of an error true value ε0 that is a true value of the error and an error amount εx.

$$ε = ε0 + ε x \qquad ( 8 )$$

Hereinafter, the description is made with respect to the determination that is made when the current integration time T is 31 days and the determination that is made when the current integration time T is 7 days in a case where it is requested to suppress an error amount εx included in a measurement error ε to less than 0.5 [mA].

In a case where the error amount εx is 0.5 [mAh], to express the absolute value of the error (Se−Sx) that is accumulated along with the lapse of the integration time in terms of capacity, the error amount εx per day becomes 12 [mAh] (−0.5 [mA]×24 [h]). Accordingly, in step S110, if the error per day is less than 12 [mAh], the correction is not performed, and if the error is 12 [mAh] or more, the correction is performed. The threshold TH2 at this point of time is 12 [mAh]/(60 [Ah]×1000)×100=0.02 [%] in terms of an SOC per day.

For example, in a case where the capacity converted value of the error (Se−Sx) is 328 [mAh] and the current integration time T in this case is 31 days, the error per day is 10.6 [mAh](≈328 [mAh]/31 [days]). This value is smaller than 12 [mAh] and hence, the control unit 120 does not perform the correction (S110: NO).

In a case where the current integration time T that is required for the accumulation of the same error of 328 [mAh] is 7 days, the error per day becomes 46.9 [mAh] that is more than 12 [mAh]. In this case, the control unit 120 determines that the correction is necessary (S110: YES), and performs steps S120, S130.

### Correction Example in S130

When it is determined that the correction is necessary in step S110, the measurement error ε is corrected. As the correction value Δε of the measurement error ε, the value calculated by formula (6) in step S100 is used. A coefficient k is a positive value of 1 or less. By setting the coefficient to satisfy the relationship k=1, the measurement error ε can be corrected with a large correction value Δε. The coefficient k may be set to a positive value of less than 1, and the correction with a such small correction value Δε may be repeated.

As in the case of the example described above, a case is considered where the SOC estimation error Se is largely estimated such that the error accumulated in 7 days is 328 [mAh]. In this case, to express the capacity in terms of the current assuming that the current is constant, 1.95 [mA](=328 [mAh]/168 [h]) is obtained. This value is the error amount εx included in the measurement error ε.

In a case where the previous-time value of the measurement error ε is 4.8 [mA], and the error amount εx directly becomes the correction value Δε when the coefficient k satisfies the relationship of k=1. From the equations (6), (7), the measurement error ε1 after the correction becomes 2.85 [mA] (=4.8 [mA]−1.95 [mA]).

Accordingly, in step S130, by replacing the measurement error ε of the current measurement value Im with 2.85 [mA] corrected from the previous-time value 4.8 [mA], the estimation accuracy of the SOC estimation error Se in the current integration method can be improved.

In a case where a positive value less than 1 is used as the coefficient k, the following result is obtained.

For example, in a case where the coefficient k is set to satisfy the relationship of k=0.5, from the equations (6), (7), the measurement error ε1 after the correction becomes 3.825 [mA] (=4.8 [mA]−1.95 [mA]×0.5). Accordingly, the measurement error ε1 after correction is set to 3.825 [mA]. The correction value Δε in the case where the coefficient k is set to satisfy the relationship of k=0.5 is smaller than the correction value Δε in the case where the coefficient k is set to satisfy the relationship of k=1.

By performing the correction each time the full charging detection method is performed thereafter, the correction is repeatedly performed so that the measurement error ε of the current is made to gradually approach the error true value ε0 and eventually takes a value close to the error true value ε0.

### 4. Description of Advantageous Effects

With the configuration described above, the estimation accuracy of the SOC estimation error Se is improved by correcting the measurement error ε included in the current measurement value Im. As a result, the SOC estimation range Y can be narrowed. In a case where the measurement error ε before the correction is estimated to be smaller than the true value, the estimation accuracy of the SOC estimation error Se is improved by the correction of the measurement error ε. Accordingly, the reliability of the SOC estimation range Y is improved.

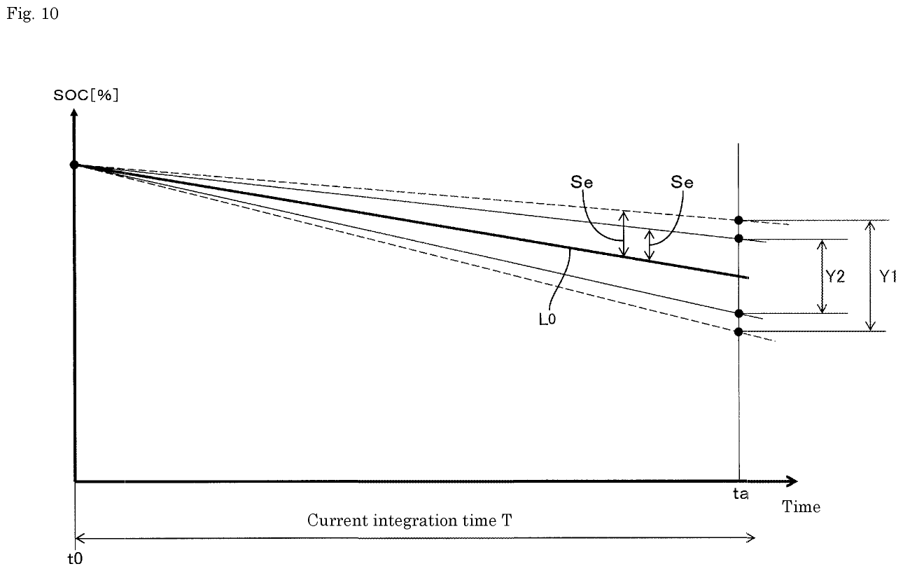

FIG. 10 is a graph illustrating an SOC estimation range. In the graph, L0 is an SOC estimation value, Y1 is an SOC estimation range when correction is not performed, and Y2 is an SOC estimation range when the correction is performed. The estimation error Se can be suppressed by correcting the measurement error ε. Accordingly, the SOC estimation range Y can be narrowed as compared with the case where the correction is not performed.

By narrowing the SOC estimation range Y, the battery performance can be maintained. For example, in the charge control of the assembled battery 60, there may be a case where a charge current is determined corresponding to an upper limit value of the SOC estimation range Y in order to prevent the degradation of the battery performance. In the configuration described above, the assembled battery 60 can be charged with an appropriate charge current corresponding to the upper limit value of the SOC estimation range Y and hence, the battery performance can be maintained.

When a use range of the SOC (for example, SOC being a value that falls within a range of from 50% to 80%) is decided, the assembled battery 60 can be charged until the upper limit value of the SOC estimation range Y reaches an upper limit value of the use range. With this configuration, the SOC estimation range Y is narrowed so that L0 can be brought close to the upper limit value of the use range whereby the performance of the assembled battery 60 can be utilized.

By correcting the measurement error ε, it is possible to extend the time until the SOC estimation error Se, that is an accumulation value of the measurement errors ε, reaches a threshold TH1. The frequency of performing the SOC correction by the full charging detection method can be suppressed.

By reducing the frequency of performing the SOC correction, the frequency of charging electricity for performing the SOC correction can be reduced. The regeneration cannot be received during charging of electricity to full charging. By reducing the frequency of charging electricity for performing the SOC correction, it is possible to shorten a period during which the regenerative reception is restricted. Such performance contributes to the improvement of the reduction of fuel consumption of the vehicle.

### Embodiment 2

In the embodiment 1, the measurement error ε is corrected using the second SOC estimated by the full charging detection method.

In the embodiment 2, the measurement error ε is corrected using the second SOC estimated by the full charging detection method.

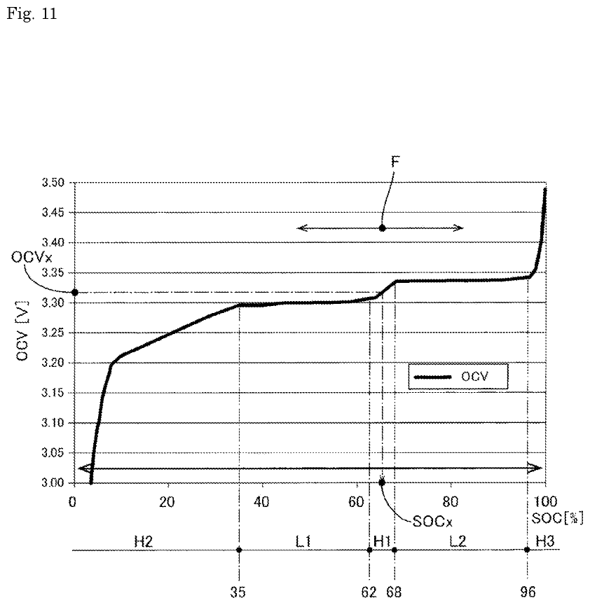

FIG. 11 is a graph illustrating an SOC-OCV correlation characteristic of a LFP/Gr-based lithium ion secondary battery cell 62 where a positive electrode is made of lithium iron phosphate and a negative electrode is made of graphite. SOC is taken on an axis of abscissas, and OCV is taken on an axis of ordinates. The OCV stands for an open circuit voltage. The OCV may be a terminal voltage of the cell 62 in a case where no current flows or a case where substantially no current flows (a case where a current value is equal to or less than a predetermined value).

A lithium ion secondary battery cell has a plurality of charge regions including: a low-change region L where a change amount of OCV with respect to a change amount of SOC is relatively low; and a high change region H where the change amount of OCV with respect to the change amount of SOC is relatively high.

To be more specific, the lithium ion secondary battery cell includes two low-change regions L1, L2, and three high change regions H1, H2, H3.

The low-change region L1 is a region where an SOC value falls within a range of 35 [%] to 62 [%], and the low-change region L2 is a region where an SOC value falls within a range of 68 [%] to 96 [%].

The low-change regions L1, L2 are plateau regions where a change amount of the OCV with respect to a change amount of the SOC is very small and the OCV is substantially constant. The plateau region is a region where a change amount of OCV with respect to a change amount of SOC is equal to or less than a predetermined value. The predetermined value is 2 [mV/%] as an example.

The first high change region H1 is a region where an SOC value falls within a range of more than 62 [%] and less than 68 [%]. The second high change region H2 is a region where an SOC value is less than 35 [%], and the third high change region H3 is a region where the SOC value is more than 96 [%].

In the OCV method, the SOC is estimated by referencing the OCV in the SOC-OCV correlation characteristic (the graph of FIG. 11). For example, the SOC in a case where the OCV is an OCVx can be estimated as an SOCx. In this manner, the second SOC can be estimated by the OCV method.

There may be a case where the upper limit value of a use range F of the assembled battery 60 is set to a value that falls within a range less than 100% such as a range from 50% to 80%. By adopting the setting having a margin with respect to the full charging such as setting an upper limit value of the use range F to less than 100%, the reception of the regeneration becomes possible.

In this example, the first high change region H1 is included in the use range F. Accordingly, even within the use range F, the second SOC can be estimated by performing the OCV method.

The OCV method may be performed by charging electricity of the assembled battery 60 not only within the use range F but also up to the third high change region H3. Further, electricity is discharged from the assembled battery 60 up to the second high change region H2.

### Other Embodiments

The present invention is not limited to the embodiments described with reference to the above description and drawings, and for example, the following embodiments are also included in the technical scope of the present invention, and various modifications other than the following can be made without departing from the gist of the present invention.

(1) In the above embodiment, the lithium ion secondary battery cell is illustrated as an example of the secondary battery cell 62. The secondary battery cell 62 is not limited to the lithium ion secondary battery cell, and may be other nonaqueous electrolyte secondary battery cells. A lead-acid battery cell may also be used. A capacitor may be used in place of the secondary battery cell. The secondary battery cell 62 and the capacitor are examples of the “energy storage cell”.

(2) The assembled battery 60 is not limited to the configuration where the plurality of secondary battery cells 62 are connected in series and parallel, and may be the configuration where the plurality of secondary battery cells 62 are connected in series or the configuration where the plurality of secondary battery cells 62 are connected in series, the configuration formed of a single cell.

(3) In the above embodiment, the battery 50 is provided for an automobile, but may be provided for a motorcycle. The battery 50 may be used for other moving bodies such as a ship, an AGV, or an aircraft.

(4) In the above-mentioned embodiment, the control unit 120 is disposed in the battery 50. The control unit 120 may be disposed outside the battery 50. That is, the control unit 120 disposed outside the battery 50 may perform the correction of the measurement error ε, the calculation of the SOC estimation error Se, and the SOC estimation. In this case, the control unit 120 may acquire information relating to the current measurement value Im and the total voltage VB from the current measurement unit 54 and the voltage measurement unit 110 disposed in the battery 50 by communication, and may perform the correction of the measurement error ε, the calculation of the SOC estimation error Se, and the estimation of the SOC.

(5) In the above embodiments, the full charging detection method and the OCV method are exemplified as the method of estimating a residual electricity amount that differs from the estimation based on an integrated value of a current. Any method other than the full charging detection method and the OCV method may be used provided that such a method can estimate a residual electricity amount without using an integrated value of a current.

1. An estimation device for estimating a residual electricity amount of an energy storage cell or an assembled battery, wherein the estimation device is configured to perform:
first processing of estimating the residual electricity amount based on an integrated value of a current of the energy storage cell or the assembled battery;
second processing of estimating an accumulated error of the residual electricity amount based on an integrated value of a measurement error of the current;
third processing of estimating the residual electricity amount by a method that differs from the first processing;
fourth processing of calculating a residual electricity amount difference that is a difference between the residual electricity amount estimated in the first processing and the residual electricity amount estimated in the third processing; and
fifth processing of calculating a correction value of the measurement error based on the accumulated error and the residual electricity amount difference.

2. The estimation device according to claim 1, wherein
the estimation device performs sixth processing of correcting the measurement error based on the correction value calculated in the fifth processing, and
the estimation device performs, after performing the sixth processing, the second processing using the corrected measurement error.

3. The estimation device according to claim 2, wherein
the estimation device performs the sixth processing so as to correct the measurement error in a case where a difference between the accumulated error and the residual electricity amount difference exceeds a threshold.

4. The estimation device according to claim 1, wherein
in the third processing, the estimation device estimates the residual electricity amount of the energy storage cell or the assembled battery by a full charging detection method in which the energy storage cell or the assembled battery is fully charged.

5. An energy storage apparatus comprising:
an energy storage cell or an assembled battery; and
a current measurement unit that measures a current of the energy storage cell or the assembled battery; and
the estimation device according to claim 1.

6. A method of estimating a residual electricity amount of an energy storage cell or an assembled battery, the method comprising:
a first step of estimating the residual electricity amount based on an integrated value of a current of the energy storage cell or the assembled battery;
a second step of estimating an accumulated error of the residual electricity amount based on an integrated value of a measurement error of the current;
a third step of estimating the residual electricity amount by a method that differs from the first step;
a fourth step of calculating a residual electricity amount difference that is a difference between the residual electricity amount estimated in the first step and the residual electricity amount estimated in the third step; and
a fifth step of calculating a correction value of the measurement error based on a difference between the accumulated error and the residual electricity amount difference.
